(19) United States
(12) Patent Application Publication
(10) Pub. No.: US 2026/0040936 A1
(43) Pub. Date: Feb. 5, 2026

(54) SEMICONDUCTOR PACKAGE INCLUDING INTERCONNECT STRUCTURES

(71) Applicant: SK hynix Inc., Icheon-si Gyeonggi-do (KR)

(72) Inventors: Hyo Sun LEE, Icheon-si Gyeonggi-do (KR); Wan Choon PARK, Icheon-si Gyeonggi-do (KR)

(73) Assignee: SK hynix Inc., Icheon-si Gyeonggi-do (KR)

(21) Appl. No.: 18/975,875

(22) Filed: Dec. 10, 2024

(30) Foreign Application Priority Data
Jul. 30, 2024 (KR) 10-2024-0100630

(51) Int. Cl. H01L 23/528; H01L 23/31

(52) U.S. Cl. CPC H01L 23/5283; H01L 23/3192

(57) ABSTRACT

A semiconductor package includes a lower interconnect structure. The lower interconnect structure includes a lower insulating layer and lower interconnect patterns. A first encapsulation layer is disposed on the lower interconnect structure. A pillar electrode penetrating the first encapsulation layer and connected to the lower interconnect patterns is provided. An upper interconnect structure disposed within the first encapsulation layer and having an upper insulating layer and upper interconnect patterns is provided. A distance between an upper surface of the lower interconnect structure and an uppermost end of the first encapsulation layer is larger than a distance between the upper surface of the lower interconnect structure and an uppermost end of the upper interconnect structure. A second encapsulation layer is disposed on the first encapsulation layer. A semiconductor chip disposed within the second encapsulation layer and connected to the pillar electrode and upper interconnect patterns is provided.

### CROSS-REFERENCE TO RELATED APPLICATION

The present application claims priority under 35 U.S.C. § 119 (a) to Korean Patent Application No. 10-2024-0100630 filed in the Korean Intellectual Property Office on Jul. 30, 2024, which application is incorporated herein by reference in its entirety.

### BACKGROUND

### 1. Technical Field

Various embodiments of the present disclosure generally relate to a semiconductor package and a method for forming the semiconductor package.

### 2. Related Art

In response to the light weight, thinness, compactness and miniaturization of a semiconductor package, a technology of mounting a semiconductor chip on a redistribution layer is being attempted. The redistribution layer may include an insulating layer and interconnect patterns. The redistribution layer may include a region where interconnect patterns having a coarse pitch are required and a region where interconnect patterns having a fine pitch are required.

### SUMMARY

A semiconductor package according to an embodiment of the present disclosure may include a lower interconnect structure. The lower interconnect structure may include a lower insulating layer and a plurality of lower interconnect patterns. A first encapsulation layer may be disposed on the lower interconnect structure. A pillar electrode penetrating the first encapsulation layer and connected to the plurality of lower interconnect patterns may be provided. An upper interconnect structure disposed within the first encapsulation layer and having an upper insulating layer and a plurality of upper interconnect patterns may be provided. A distance between an upper surface of the lower interconnect structure and an uppermost end of the first encapsulation layer may be larger than a distance between the upper surface of the lower interconnect structure and an uppermost end of the upper interconnect structure. A second encapsulation layer may be disposed on the first encapsulation layer. A semiconductor chip disposed within the second encapsulation layer and connected to the pillar electrode and the plurality of upper interconnect patterns may be provided.

A semiconductor package according to an embodiment of the present disclosure may include a lower interconnect structure. The lower interconnect structure may include a lower insulating layer and a plurality of lower interconnect patterns. A first encapsulation layer may be disposed on the lower interconnect structure. A plurality of pillar electrodes penetrating the first encapsulation layer and connected to the plurality of lower interconnect patterns may be provided. An upper interconnect structure disposed within the first encapsulation layer and having an upper insulating layer and a plurality of upper interconnect patterns may be provided. A distance between an upper surface of the lower interconnect structure and an uppermost end of the first encapsulation layer may be larger than a distance between the upper surface of the lower interconnect structure and an uppermost end of the upper interconnect structure. A second encapsulation layer may be disposed on the first encapsulation layer. First and second semiconductor chips disposed within the second encapsulation layer and connected to the plurality of pillar electrodes and the plurality of upper interconnect patterns may be provided.

### BRIEF DESCRIPTION OF THE DRAWINGS

FIG. 1 is a cross-sectional view for explaining a semiconductor package according to embodiments of the present disclosure.

FIGS. 2 and 3 are partial views for explaining some components of FIG. 1 according to some embodiments of the present disclosure.

FIGS. 4 to 7 are partial views for explaining a part of FIG. 1 according to some embodiments of the present disclosure.

FIGS. 8 to 12 are partial views for explaining some components of FIG. 1 according to some embodiments of the present disclosure.

FIG. 13 is a cross-sectional view for explaining a semiconductor package according to embodiments of the present disclosure.

FIGS. 14 to 28 are cross-sectional views for explaining a method for forming a semiconductor package according to embodiments of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

Various embodiments of the present disclosure are directed to providing a semiconductor package including interconnect structures and a method for forming the same.

According to various embodiments of the present disclosure, a semiconductor package including interconnect structures and a method for forming the same may be provided.

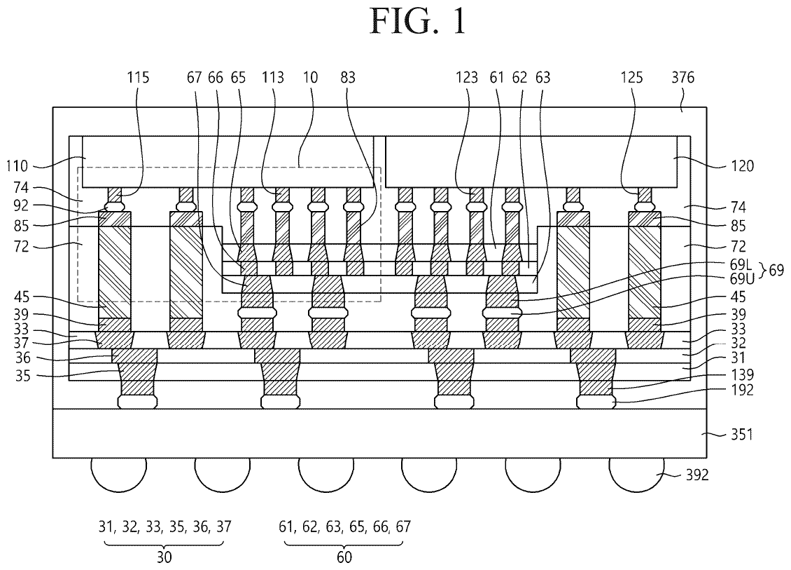

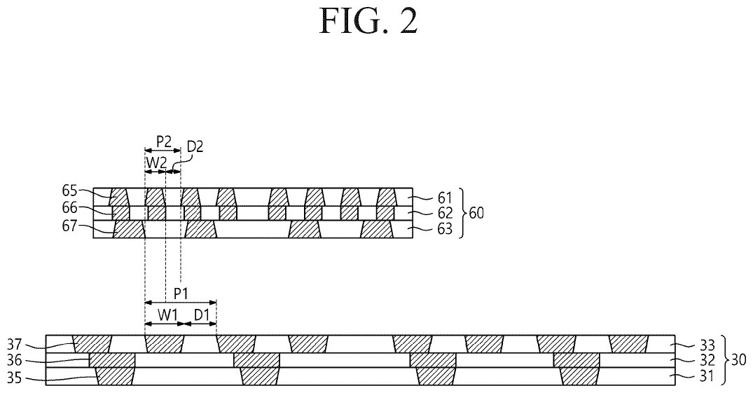

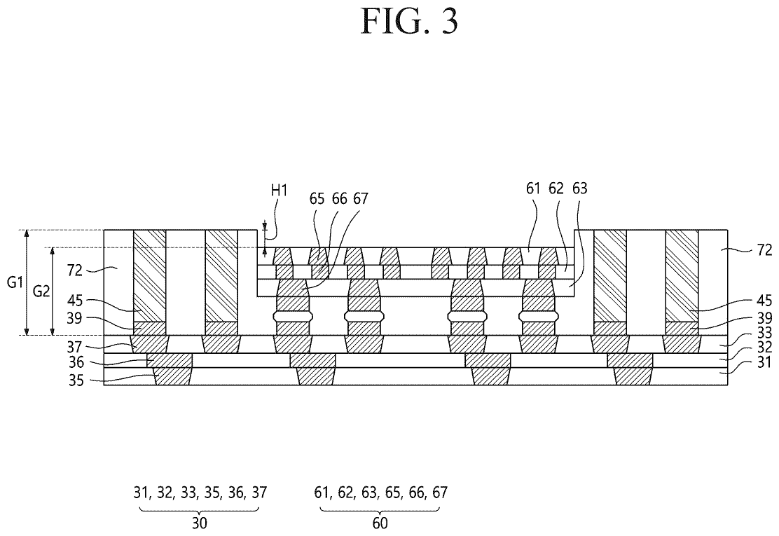

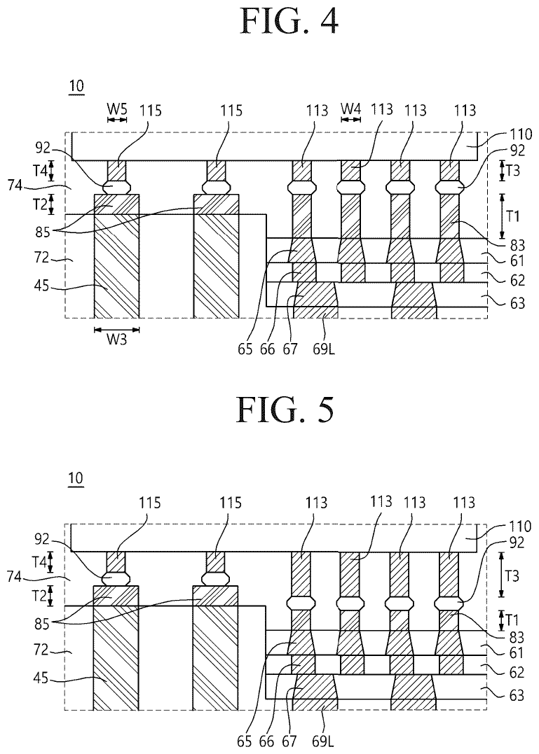

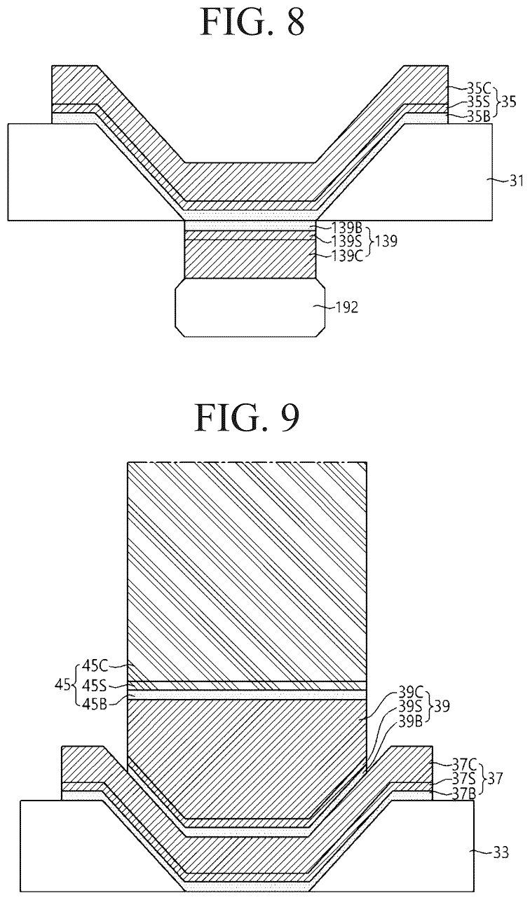

FIG. 1 is a cross-sectional view for explaining a semiconductor package according to embodiments of the present disclosure. FIG. 2 is a partial view for explaining a lower interconnect structure 30 and an upper interconnect structure 60 of FIG. 1 according to some embodiments of the present disclosure. FIG. 3 is a partial view for explaining some components of FIG. 1 according to some embodiments of the present disclosure. FIGS. 4 to 7 are partial views for explaining a part 10 of FIG. 1 according to some embodiments of the present disclosure. FIGS. 8 to 12 are partial views for explaining some components of FIG. 1 according to some embodiments of the present disclosure.

Referring to FIG. 1, the semiconductor package according to various embodiments of the present disclosure may include a lower interconnect structure 30, a first lower electrode 39, a pillar electrode 45, an upper interconnect structure 60, an intermediate electrode 69, a first encapsulation layer 72, a second encapsulation layer 74, a first upper electrode 83, a second upper electrode 85, an upper solder interconnection 92, a first semiconductor chip 110, a first chip electrode 113, a second chip electrode 115, a second semiconductor chip 120, a third chip electrode 123, a fourth chip electrode 125, a second lower electrode 139, a lower solder interconnection 192, a package substrate 351, a third encapsulation layer 376, and an external terminal 392. In an embodiment, each of the lower interconnect structure 30 and the upper interconnect structure 60 may include a multilayer redistribution layer (MLR).

The lower interconnect structure 30 may include lower insulating layers 31, 32 and 33 and a plurality of lower interconnect patterns 35, 36 and 37. In an embodiment, the lower insulating layers 31, 32 and 33 may include a first lower insulating layer 31, a second lower insulating layer 32 and a third lower insulating layer 33. The plurality of lower interconnect patterns 35, 36 and 37 may include a first lower interconnect pattern 35, a second lower interconnect pattern 36 and a third lower interconnect pattern 37.

The upper interconnect structure 60 may include upper insulating layers 61, 62 and 63 and a plurality of upper interconnect patterns 65, 66 and 67. In an embodiment, the upper insulating layers 61, 62 and 63 may include a first upper insulating layer 61, a second upper insulating layer 62 and a third upper insulating layer 63. The plurality of upper interconnect patterns 65, 66 and 67 may include a first upper interconnect pattern 65, a second upper interconnect pattern 66 and a third upper interconnect pattern 67. The intermediate electrode 69 may include a first intermediate electrode 69L and a second intermediate electrode 69U.

The external terminal 392 may be disposed on one surface (e.g., the lower surface) of the package substrate 351. The lower interconnect structure 30 may be disposed on the other surface (e.g., the upper surface) of the package substrate 351. The first encapsulation layer 72 may be disposed on the lower interconnect structure 30. The pillar electrode 45 and the upper interconnect structure 60 may be disposed within the first encapsulation layer 72. The pillar electrode 45 may be connected to the lower interconnect structure 30 by penetrating the first encapsulation layer 72. The pillar electrode 45 may be disposed adjacent to the edge of the lower interconnect structure 30. A plurality of pillar electrodes 45 may be repeatedly disposed along the edge of the lower interconnect structure 30.

In an embodiment, the upper interconnect structure 60 may overlap the center of the lower interconnect structure 30. The first encapsulation layer 72 may completely surround the side surface of the upper interconnect structure 60. The first encapsulation layer 72 may extend between the upper interconnect structure 60 and the lower interconnect structure 30. The plurality of pillar electrodes 45 may be disposed adjacent to both sides of the upper interconnect structure 60.

The second encapsulation layer 74 may be disposed on the first encapsulation layer 72 and the upper interconnect structure 60. The first semiconductor chip 110 and the second semiconductor chip 120 may be disposed within the second encapsulation layer 74. Each of the first semiconductor chip 110 and the second semiconductor chip 120 may overlap the first encapsulation layer 72 and the upper interconnect structure 60. The second encapsulation layer 74 may completely surround the side surfaces of the first semiconductor chip 110 and the second semiconductor chip 120. The second encapsulation layer 74 may extend between the first semiconductor chip 110 and the first encapsulation layer 72, between the first semiconductor chip 110 and the upper interconnect structure 60, between the second semiconductor chip 120 and the upper interconnect structure 60 and between the second semiconductor chip 120 and the first encapsulation layer 72.

In an embodiment, the minimum distance between the first semiconductor chip 110 and the first encapsulation layer 72 may be smaller than the minimum distance between the first semiconductor chip 110 and the upper interconnect structure 60. The minimum distance between the second semiconductor chip 120 and the first encapsulation layer 72 may be smaller than the minimum distance between the second semiconductor chip 120 and the upper interconnect structure 60. In an embodiment, the first encapsulation layer 72 is closer in distance to the first semiconductor chip 110 than the upper interconnect structure 60 is to the first semiconductor chip 110. The thickness of the second encapsulation layer 74 between the first semiconductor chip 110 and the upper interconnect structure 60 may be larger than the thickness of the second encapsulation layer 74 between the first semiconductor chip 110 and the first encapsulation layer 72. The thickness of the second encapsulation layer 74 between the second semiconductor chip 120 and the upper interconnect structure 60 may be larger than the thickness of the second encapsulation layer 74 between the second semiconductor chip 120 and the first encapsulation layer 72.

The third encapsulation layer 376 which covers the lower interconnect structure 30, the first encapsulation layer 72, the second encapsulation layer 74, the first semiconductor chip 110 and the second semiconductor chip 120 may be disposed on the package substrate 351. In an embodiment, the third encapsulation layer 376 may extend between the package substrate 351 and the lower interconnect structure 30. The lower solder interconnection 192 may penetrate the third encapsulation layer 376 to be connected to the package substrate 351. The second lower electrode 139 may be disposed between the lower solder interconnection 192 and the first lower interconnect pattern 35. The second lower electrode 139 may penetrate the third encapsulation layer 376 to be connected to the lower solder interconnection 192 and the first lower interconnect pattern 35. The lower interconnect structure 30 may include the plurality of lower interconnect patterns 35, 36 and 37 which have a coarser pitch than the plurality of upper interconnect patterns 65, 66 and 67. The lower interconnect structure 30 will be described again with reference to FIG. 2.

The first lower electrode 39 may be disposed on the lower interconnect structure 30. The first encapsulation layer 72 may surround the side surface of the first lower electrode 39. The first lower electrode 39 may be aligned on the third lower interconnect pattern 37. The first lower electrode 39 may contact the third lower interconnect pattern 37. A plurality of first lower electrodes 39 may be disposed at regular intervals. The pillar electrode 45 may penetrate the first encapsulation layer 72 to contact the first lower electrode 39. The pillar electrode 45 may have a thickness larger than a horizontal width. For example, as illustrated in FIG. 1, the pillar electrode 45 has a thickness larger than a horizontal width. In an embodiment, for reference, the thickness may be in the vertical direction from the package substrate 351 to the first semiconductor chip 110 and the horizontal width may be in the direction from the first semiconductor chip 110 to the second semiconductor chip 120. The plurality of pillar electrodes 45 may be connected to a plurality of third lower interconnect patterns 37 through the plurality of first lower electrodes 39.

The intermediate electrode 69 may be disposed between the upper interconnect structure 60 and the first lower electrode 39. The first encapsulation layer 72 may surround the side surface of the intermediate electrode 69. The second intermediate electrode 69U may be disposed between the first lower electrode 39 and the first intermediate electrode 69L. The second intermediate electrode 69U may contact the first lower electrode 39 and the first intermediate electrode 69L. The first intermediate electrode 69L may be disposed between the third upper interconnect pattern 67 and the second intermediate electrode 69U. The first intermediate electrode 69L may contact the third upper interconnect pattern 67 and the second intermediate electrode 69U. The upper interconnect structure 60 may include the plurality of upper interconnect patterns 65, 66 and 67 which have a finer pitch than the plurality of lower interconnect patterns 35, 36 and 37. The upper interconnect structure 60 will be described again with reference to FIG. 2.

The first upper electrode 83 may be disposed on the first upper interconnect pattern 65. The second upper electrode 85 may be disposed on the pillar electrode 45. The upper solder interconnection 92 may be disposed on each of the first upper electrode 83 and the second upper electrode 85. Each of the first upper electrode 83, the second upper electrode 85 and the upper solder interconnection 92 may be disposed in a plural number. The first chip electrode 113, the second chip electrode 115, the third chip electrode 123 and the fourth chip electrode 125 may be disposed on the plurality of upper solder interconnections 92. The second encapsulation layer 74 may surround the side surfaces of the first upper electrode 83, the second upper electrode 85, the upper solder interconnection 92, the first chip electrode 113, the second chip electrode 115, the third chip electrode 123 and the fourth chip electrode 125.

The first semiconductor chip 110 may be connected to the first upper interconnect pattern 65 through the first chip electrode 113, the upper solder interconnection 92 and the first upper electrode 83. The first semiconductor chip 110 may be connected to the pillar electrode 45 through the second chip electrode 115, the upper solder interconnection 92 and the second upper electrode 85. The second semiconductor chip 120 may be connected to the first upper interconnect pattern 65 through the third chip electrode 123, the upper solder interconnection 92 and the first upper electrode 83. The second semiconductor chip 120 may be connected to the pillar electrode 45 through the fourth chip electrode 125, the upper solder interconnection 92 and the second upper electrode 85.

Referring to FIG. 2, the lower interconnect structure 30 may include the lower insulating layers 31, 32 and 33 and the plurality of lower interconnect patterns 35, 36 and 37. In an embodiment, the lower insulating layers 31, 32 and 33 may include the first lower insulating layer 31, the second lower insulating layer 32 and the third lower insulating layer 33 which are sequentially stacked. The plurality of lower interconnect patterns 35, 36 and 37 may include the first lower interconnect pattern 35, the second lower interconnect pattern 36 and the third lower interconnect pattern 37.

The first lower interconnect pattern 35 may be disposed in the first lower insulating layer 31. The first lower interconnect pattern 35 may penetrate the first lower insulating layer 31. The second lower interconnect pattern 36 may be disposed in the second lower insulating layer 32. The second lower interconnect pattern 36 may penetrate the second lower insulating layer 32 to contact the first lower interconnect pattern 35. The third lower interconnect pattern 37 may be disposed in the third lower insulating layer 33. The third lower interconnect pattern 37 may penetrate the third lower insulating layer 33 to contact the second lower interconnect pattern 36.

The upper interconnect structure 60 may include the upper insulating layers 61, 62 and 63 and the plurality of upper interconnect patterns 65, 66 and 67. In an embodiment, the upper insulating layers 61, 62 and 63 may include the first upper insulating layer 61, the second upper insulating layer 62 and the third upper insulating layer 63. The second upper insulating layer 62 may be disposed between the first upper insulating layer 61 and the third upper insulating layer 63. The third upper insulating layer 63 may constitute the lowermost layer of the upper interconnect structure 60. The first upper insulating layer 61 may constitute the uppermost layer of the upper interconnect structure 60.

The plurality of upper interconnect patterns 65, 66 and 67 may include the first upper interconnect pattern 65, the second upper interconnect pattern 66 and the third upper interconnect pattern 67. The third upper interconnect pattern 67 may be disposed in the third upper insulating layer 63. The third upper interconnect pattern 67 may penetrate the third upper insulating layer 63. The second upper interconnect pattern 66 may be disposed in the second upper insulating layer 62. The second upper interconnect pattern 66 may penetrate the second upper insulating layer 62 to contact the third upper interconnect pattern 67. The first upper interconnect pattern 65 may be disposed in the first upper insulating layer 61. The first upper interconnect pattern 65 may penetrate the first upper insulating layer 61 to contact the second upper interconnect pattern 66.

The plurality of lower interconnect patterns 35, 36 and 37 may be disposed to have a coarse pitch. In an embodiment, the third lower interconnect pattern 37 has a first width W1. The third lower interconnect pattern 37 may be disposed in a plural number at regular intervals. The spacing between the plurality of third lower interconnect patterns 37 has a first distance D1. A first pitch P1 of the plurality of third lower interconnect patterns 37 may be expressed by the sum of the first width W1 and the first distance D1. Each of the first lower interconnect pattern 35 and the second lower interconnect pattern 36 may be disposed in a plural number at regular intervals. Each of the first lower interconnect pattern 35 and the second lower interconnect pattern 36 may be disposed to have a pitch similar to or larger than the first pitch P1.

At least some of the plurality of upper interconnect patterns 65, 66 and 67 may be disposed to have a fine pitch. In an embodiment, the first upper interconnect pattern 65 has a second width W2. The first upper interconnect pattern 65 may be disposed in a plural number at regular intervals. The spacing between the plurality of first upper interconnect patterns 65 has a second distance D2. A second pitch P2 of the plurality of first upper interconnect patterns 65 is expressed by the sum of the second width W2 and the second distance D2. The second width W2 may be smaller than the first width W1. The second distance D2 may be smaller than the first distance D1. The second pitch P2 may be smaller than the first pitch P1.

Each of the second upper interconnect pattern 66 and the third upper interconnect pattern 67 may be disposed in a plural number at regular intervals. Each of the second upper interconnect pattern 66 and the third upper interconnect pattern 67 may be disposed to have a pitch similar to or larger than the second pitch P2. In an embodiment, the second upper interconnect pattern 66 may be disposed to have a pitch similar to the second pitch P2. The third upper interconnect pattern 67 may be disposed to have a pitch larger than the second pitch P2 and substantially the same as the first pitch P1 of the third lower interconnect pattern 37.

Referring to FIG. 3, the upper surface of the first encapsulation layer 72 and the upper surface of the pillar electrode 45 may form substantially the same plane. The upper surface of the first encapsulation layer 72 and the upper surface of the upper interconnect structure 60 may be disposed at different levels. The upper surface of the upper interconnect structure 60 may be disposed at a lower level than the upper surface of the first encapsulation layer 72. The upper surface of the first encapsulation layer 72 and the upper surface of the upper interconnect structure 60 may have a level difference H1. One surfaces (e.g., the upper surfaces) of the first upper insulating layer 61 and the first upper interconnect pattern 65 may form substantially the same plane. The upper surfaces of the first upper insulating layer 61 and the first upper interconnect pattern 65 may be disposed at a lower level than the upper surface of the first encapsulation layer 72. The distance between one surface (e.g., the upper surface) of the lower interconnect structure 30 and the uppermost end of the first encapsulation layer 72 may be larger than the distance between one surface (e.g., the upper surface) of the lower interconnect structure 30 and the uppermost end of the upper interconnect structure 60. In an embodiment, the distance between an upper surface of the lower interconnect structure 30 and an uppermost end of the first encapsulation layer 72 may be a first distance G1 and a distance between the upper surface of the lower interconnect structure 30 and an uppermost end of the upper interconnect structure 60 may be a second distance G2. In an embodiment, the first distance G1 may be larger than the second distance G2.

Referring to FIG. 4, the first semiconductor chip 110 may overlap the first encapsulation layer 72 and the upper interconnect structure 60 in the vertical direction. The second encapsulation layer 74 may extend between the first semiconductor chip 110 and the first encapsulation layer 72 and between the first semiconductor chip 110 and the upper interconnect structure 60.

The first upper electrode 83, the upper solder interconnection 92 and the first chip electrode 113 may penetrate the second encapsulation layer 74 between the first semiconductor chip 110 and the upper interconnect structure 60. The first upper electrode 83 may contact the first upper interconnect pattern 65. The first chip electrode 113 may contact the first semiconductor chip 110. The upper solder interconnection 92 may contact the first upper electrode 83 and the first chip electrode 113.

The second upper electrode 85, the upper solder interconnection 92 and the second chip electrode 115 may penetrate the second encapsulation layer 74 between the first semiconductor chip 110 and the pillar electrode 45. The second upper electrode 85 may contact the pillar electrode 45. The second chip electrode 115 may contact the first semiconductor chip 110. The upper solder interconnection 92 may contact the second upper electrode 85 and the second chip electrode 115.

The first upper electrode 83 has a first thickness T1. The second upper electrode 85 has a second thickness T2. The first thickness T1 of the first upper electrode 83 may be larger than the second thickness T2 of the second upper electrode 85. The first chip electrode 113 has a third thickness T3. The second chip electrode 115 has a fourth thickness T4. The third thickness T3 of the first chip electrode 113 may be substantially the same as the fourth thickness T4 of the second chip electrode 115.

The pillar electrode 45 has a third width W3. The first chip electrode 113 has a fourth width W4. The second chip electrode 115 has a fifth width W5. The fourth width W4 of the first chip electrode 113 may be substantially the same as the fifth width W5 of the second chip electrode 115. The fifth width W5 of the second chip electrode 115 may be smaller than the third width W3 of the pillar electrode 45. The second upper electrode 85 may have a horizontal width similar to the third width W3 of the pillar electrode 45.

In an embodiment, the second semiconductor chip 120 (see FIG. 1), the third chip electrode 123 (see FIG. 1) and the fourth chip electrode 125 (see FIG. 1) may include structures similar to the first semiconductor chip 110, the first chip electrode 113 and the second chip electrode 115.

Referring to FIG. 5, in an embodiment, the first thickness T1 of the first upper electrode 83 may be substantially the same as the second thickness T2 of the second upper electrode 85. The third thickness T3 of the first chip electrode 113 may be larger than the fourth thickness T4 of the second chip electrode 115.

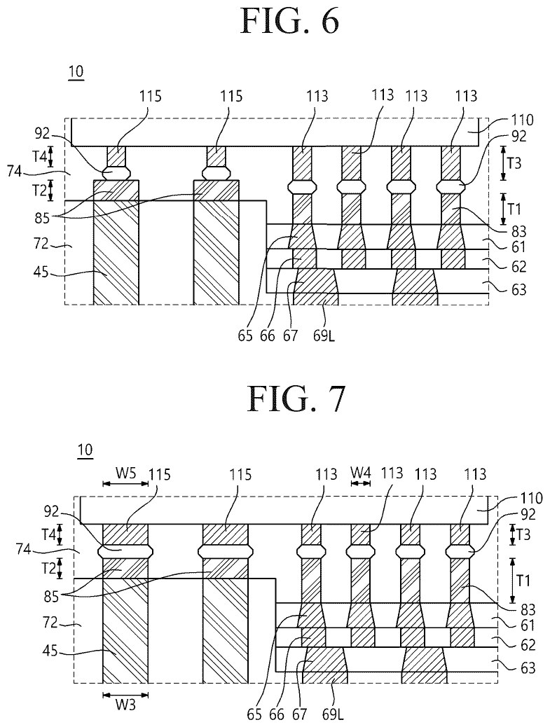

Referring to FIG. 6, in an embodiment, the first thickness T1 of the first upper electrode 83 may be larger than the second thickness T2 of the second upper electrode 85. The third thickness T3 of the first chip electrode 113 may be larger than the fourth thickness T4 of the second chip electrode 115.

Referring to FIG. 7, in an embodiment, the fifth width W5 of the second chip electrode 115 may be larger than the fourth width W4 of the first chip electrode 113. In an embodiment, a horizontal width of the second chip electrode 115 is larger than a horizontal width of the first chip electrode 113. In an embodiment, the horizontal width of the second chip electrode 115 may include the fifth width W5 and the horizontal width of the first chip electrode 113 may include the fourth width W4. The fifth width W5 of the second chip electrode 115 may be similar to the third width W3 of the pillar electrode 45. The second upper electrode 85 may have a horizontal width similar to the third width W3 of the pillar electrode 45.

Referring to FIG. 8, the first lower interconnect pattern 35 may penetrate the first lower insulating layer 31 to contact the second lower electrode 139. The interface between the first lower interconnect pattern 35 and the first lower insulating layer 31 may include an inclined surface. The second lower electrode 139 may contact the first lower interconnect pattern 35 and the lower solder interconnection 192.

The first lower interconnect pattern 35 may include a first lower interconnect barrier layer 35B, a first lower interconnect seed layer 35S and a first lower interconnect conductive layer 35C which are sequentially stacked. The second lower electrode 139 may include a second lower electrode barrier layer 139B, a second lower electrode seed layer 139S and a second lower electrode conductive layer 139C. The first lower interconnect barrier layer 35B may contact the first lower insulating layer 31 and the second lower electrode 139. The first lower interconnect seed layer 35S may be disposed between the first lower interconnect barrier layer 35B and the first lower interconnect conductive layer 35C.

The second lower electrode barrier layer 139B may contact the first lower interconnect pattern 35. The second lower electrode seed layer 139S may be disposed between the second lower electrode barrier layer 139B and the second lower electrode conductive layer 139C. The second lower electrode conductive layer 139C may contact the second lower electrode seed layer 139S and the lower solder interconnection 192. In an embodiment, the first lower interconnect barrier layer 35B may contact the second lower electrode barrier layer 139B.

Referring to FIG. 9, the third lower interconnect pattern 37 may penetrate the third lower insulating layer 33. The first lower electrode 39 may contact the third lower interconnect pattern 37. The pillar electrode 45 may contact the first lower electrode 39. The third lower interconnect pattern 37 may include a third lower interconnect barrier layer 37B, a third lower interconnect seed layer 37S and a third lower interconnect conductive layer 37C which are sequentially stacked. The first lower electrode 39 may include a first lower electrode barrier layer 39B, a first lower electrode seed layer 39S and a first lower electrode conductive layer 39C which are sequentially stacked. The pillar electrode 45 may include a pillar electrode barrier layer 45B, a pillar electrode seed layer 45S and a pillar electrode conductive layer 45C which are sequentially stacked. In an embodiment, the first lower electrode barrier layer 39B may contact the third lower interconnect conductive layer 37C. The pillar electrode barrier layer 45B may contact the first lower electrode conductive layer 39C.

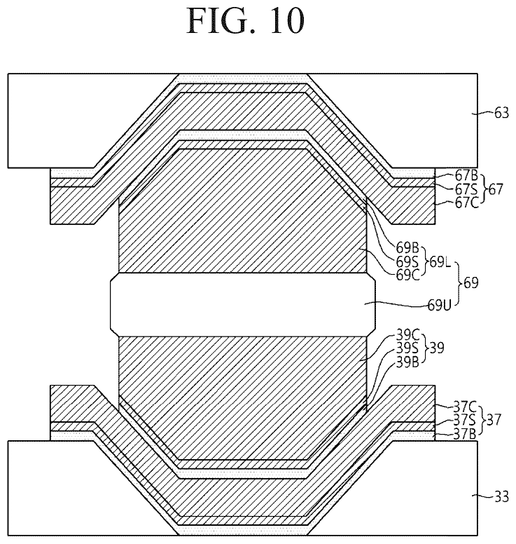

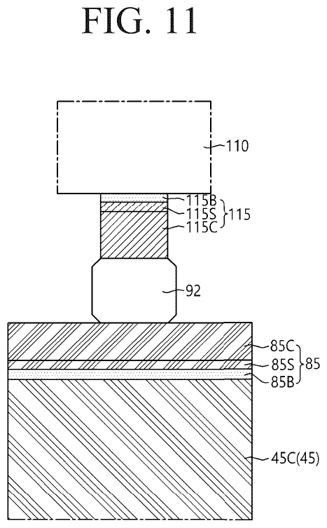

Referring to FIG. 10, the third lower interconnect pattern 37 may penetrate the third lower insulating layer 33. The first lower electrode 39 may contact the third lower interconnect pattern 37. The intermediate electrode 69 may be disposed on the first lower electrode 39. The intermediate electrode 69 may include the first intermediate electrode 69L and the second intermediate electrode 69U. The second intermediate electrode 69U may contact the first lower electrode 39. The third upper interconnect pattern 67 may contact the first intermediate electrode 69L. The third upper interconnect pattern 67 may penetrate the third upper insulating layer 63.

The first intermediate electrode 69L may include a first intermediate electrode barrier layer 69B, a first intermediate electrode seed layer 69S and a first intermediate electrode conductive layer 69C. The first intermediate electrode seed layer 69S may be disposed between the first intermediate electrode barrier layer 69B and the first intermediate electrode conductive layer 69C. The first intermediate electrode conductive layer 69C may contact the second intermediate electrode 69U. The third upper interconnect pattern 67 may include a third upper interconnect barrier layer 67B, a third upper interconnect seed layer 67S and a third upper interconnect conductive layer 67C. The third upper interconnect seed layer 67S may be disposed between the third upper interconnect barrier layer 67B and the third upper interconnect conductive layer 67C. The third upper interconnect conductive layer 67C may contact the first intermediate electrode barrier layer 69B.

Referring to FIG. 11, the pillar electrode 45 may include a pillar electrode conductive layer 45C. The second upper electrode 85 may be disposed on the pillar electrode conductive layer 45C. The second upper electrode 85 may include a second upper electrode barrier layer 85B, a second upper electrode seed layer 85S and a second upper electrode conductive layer 85C which are sequentially stacked. The second upper electrode barrier layer 85B may contact the pillar electrode conductive layer 45C. The upper solder interconnection 92 may contact the second upper electrode conductive layer 85C.

The second chip electrode 115 may be disposed on the upper solder interconnection 92. The second chip electrode 115 may include a second chip electrode barrier layer 115B, a second chip electrode seed layer 115S and a second chip electrode conductive layer 115C. The second chip electrode seed layer 115S may be disposed between the second chip electrode barrier layer 115B and the second chip electrode conductive layer 115C. The second chip electrode conductive layer 115C may contact the upper solder interconnection 92. The second chip electrode 115 may be disposed between the first semiconductor chip 110 and the upper solder interconnection 92. The second chip electrode barrier layer 115B may contact the first semiconductor chip 110.

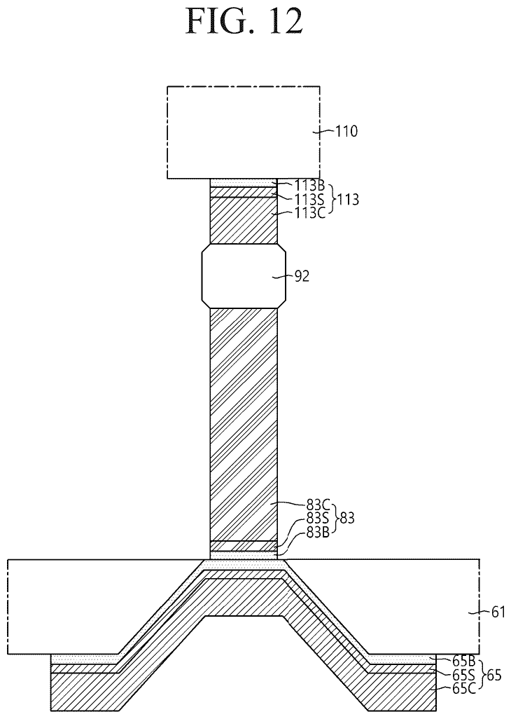

Referring to FIG. 12, the first upper interconnect pattern 65 may penetrate the first upper insulating layer 61. The first upper interconnect pattern 65 may include a first upper interconnect barrier layer 65B, a first upper interconnect seed layer 65S and a first upper interconnect conductive layer 65C. The first upper interconnect seed layer 65S may be disposed between the first upper interconnect barrier layer 65B and the first upper interconnect conductive layer 65C. The first upper electrode 83 may be disposed on the first upper interconnect pattern 65. The first upper electrode 83 may include a first upper electrode barrier layer 83B, a first upper electrode seed layer 83S and a first upper electrode conductive layer 83C which are sequentially stacked. The first upper electrode barrier layer 83B may contact the first upper interconnect barrier layer 65B.

The upper solder interconnection 92 may be disposed on the first upper electrode 83. The upper solder interconnection 92 may contact the first upper electrode conductive layer 83C. The first chip electrode 113 may be disposed between the upper solder interconnection 92 and the first semiconductor chip 110. The first chip electrode 113 may include a first chip electrode barrier layer 113B, a first chip electrode seed layer 113S and a first chip electrode conductive layer 113C. The first chip electrode seed layer 113S may be disposed between the first chip electrode barrier layer 113B and the first chip electrode conductive layer 113C. The first chip electrode conductive layer 113C may contact the upper solder interconnection 92. The first chip electrode barrier layer 113B may contact the first semiconductor chip 110.

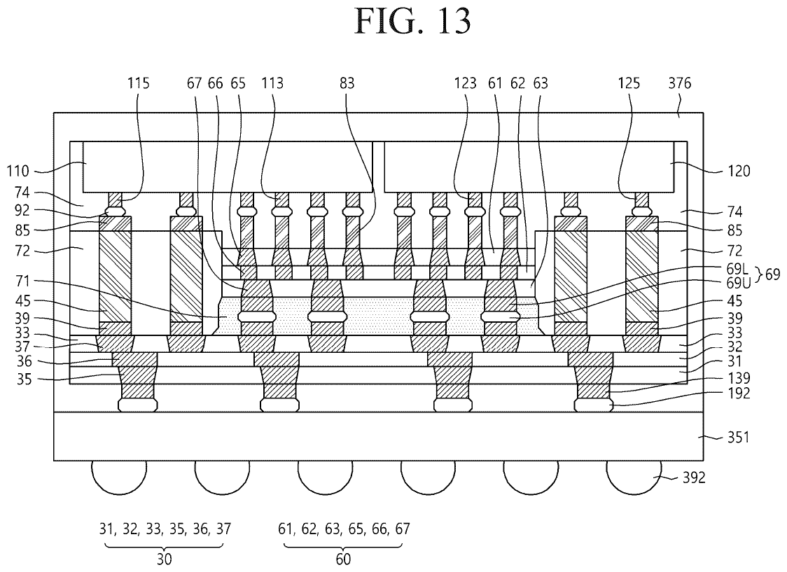

FIG. 13 is a cross-sectional view for explaining a semiconductor package according to embodiments of the present disclosure.

Referring to FIG. 13, an underfill layer 71 may be disposed between the lower interconnect structure 30 and the upper interconnect structure 60. The first lower electrode 39 and the intermediate electrode 69 may be connected to the lower interconnect structure 30 and the upper interconnect structure 60 by penetrating the underfill layer 71. The first encapsulation layer 72 may surround the side surface of the underfill layer 71.

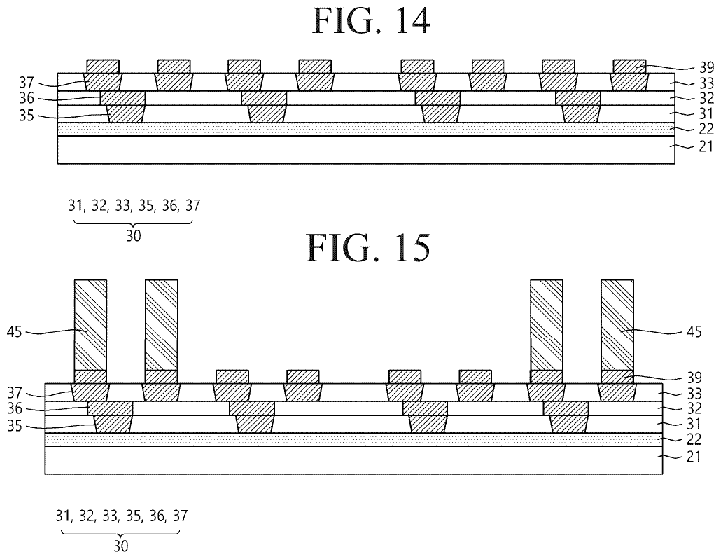

FIGS. 14 to 26 are cross-sectional views for explaining a method for forming a semiconductor package according to embodiments of the present disclosure. In an embodiment, the method for forming a semiconductor package according to the embodiments of the present disclosure may include a semi-additive process (SAP).

Referring to FIG. 14, a first buffer layer 22 may be formed on a first substrate 21. A lower interconnect structure 30 may be formed on the first buffer layer 22. A first lower electrode 39 may be formed on the lower interconnect structure 30. The lower interconnect structure 30 may include lower insulating layers 31, 32 and 33 and a plurality of lower interconnect patterns 35, 36 and 37. In an embodiment, the lower insulating layers 31, 32 and 33 may include a first lower insulating layer 31, a second lower insulating layer 32 and a third lower insulating layer 33. The plurality of lower interconnect patterns 35, 36 and 37 may include a first lower interconnect pattern 35, a second lower interconnect pattern 36 and a third lower interconnect pattern 37.

In an embodiment, the first substrate 21 may include a glass wafer. The first buffer layer 22 may include a release layer, an adhesive or a combination thereof. The first lower insulating layer 31 may be formed on the first buffer layer 22. The first lower interconnect pattern 35 may be formed in the first lower insulating layer 31. The first lower interconnect pattern 35 may penetrate the first lower insulating layer 31 to contact the first buffer layer 22. The second lower insulating layer 32 may be formed on the first lower insulating layer 31. The second lower interconnect pattern 36 may be formed in the second lower insulating layer 32. The second lower interconnect pattern 36 may penetrate the second lower insulating layer 32 to contact the first lower interconnect pattern 35. The third lower insulating layer 33 may be formed on the second lower insulating layer 32. The third lower interconnect pattern 37 may be formed in the third lower insulating layer 33. The third lower interconnect pattern 37 may penetrate the third lower insulating layer 33 to contact the second lower interconnect pattern 36. The first lower electrode 39 may be formed on the third lower interconnect pattern 37.

In an embodiment, as illustrated in FIG. 8, the first lower interconnect pattern 35 may include a first lower interconnect barrier layer 35B, a first lower interconnect seed layer 35S and a first lower interconnect conductive layer 35C which are sequentially stacked. As illustrated in FIGS. 9 and 10, the third lower interconnect pattern 37 may include a third lower interconnect barrier layer 37B, a third lower interconnect seed layer 37S and a third lower interconnect conductive layer 37C which are sequentially stacked. The second lower interconnect pattern 36 may include a configuration similar to the first lower interconnect pattern 35 and/or the third lower interconnect pattern 37. As illustrated in FIGS. 9 and 10, the first lower electrode 39 may include a first lower electrode barrier layer 39B, a first lower electrode seed layer 39S and a first lower electrode conductive layer 39C which are sequentially stacked.

Referring to FIG. 15, a pillar electrode 45 may be formed on the first lower electrode 39. The pillar electrode 45 may be formed so that a height thereof is larger than a horizontal width thereof. In an embodiment, as illustrated in FIG. 9, the pillar electrode 45 may include a pillar electrode barrier layer 45B, a pillar electrode seed layer 45S and a pillar electrode conductive layer 45C which are sequentially stacked.

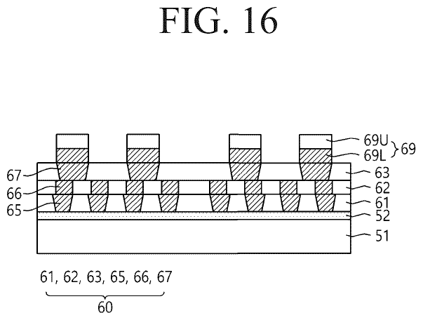

Referring to FIG. 16, a second buffer layer 52 may be formed on a second substrate 51. An upper interconnect structure 60 may be formed on the second buffer layer 52. An intermediate electrode 69 may be formed on the upper interconnect structure 60. The upper interconnect structure 60 may include upper insulating layers 61, 62 and 63 and a plurality of upper interconnect patterns 65, 66 and 67. In an embodiment, the upper insulating layers 61, 62 and 63 may include a first upper insulating layer 61, a second upper insulating layer 62 and a third upper insulating layer 63. The plurality of upper interconnect patterns 65, 66 and 67 may include a first upper interconnect pattern 65, a second upper interconnect pattern 66 and a third upper interconnect pattern 67. The intermediate electrode 69 may include a first intermediate electrode 69L and a second intermediate electrode 69U.

The second substrate 51 may include a semiconductor substrate such as a silicon wafer. The second buffer layer 52 may include a material which has an etching selectivity with respect to the second substrate 51 and the first upper insulating layer 61. The first upper insulating layer 61 may be formed on the second buffer layer 52. The first upper interconnect pattern 65 may be formed in the first upper insulating layer 61. The first upper interconnect pattern 65 may penetrate the first upper insulating layer 61 to contact the second buffer layer 52.

The second upper insulating layer 62 may be formed on the first upper insulating layer 61. The second upper interconnect pattern 66 may be formed in the second upper insulating layer 62. The second upper interconnect pattern 66 may penetrate the second upper insulating layer 62 to contact the first upper interconnect pattern 65. The third upper insulating layer 63 may be formed on the second upper insulating layer 62. The third upper interconnect pattern 67 may be formed in the third upper insulating layer 63. The third upper interconnect pattern 67 may penetrate the third upper insulating layer 63 to contact the second upper interconnect pattern 66. The first intermediate electrode 69L may be formed on the third upper interconnect pattern 67. The second intermediate electrode 69U may be formed on the first intermediate electrode 69L.

In an embodiment, as illustrated in FIG. 12, the first upper interconnect pattern 65 may include a first upper interconnect barrier layer 65B, a first upper interconnect seed layer 65S and a first upper interconnect conductive layer 65C. As illustrated in FIG. 10, the third upper interconnect pattern 67 may include a third upper interconnect barrier layer 67B, a third upper interconnect seed layer 67S and a third upper interconnect conductive layer 67C. The second upper interconnect pattern 66 may include a configuration similar to the first upper interconnect pattern 65 and/or the third upper interconnect pattern 67. As illustrated in FIG. 10, the first intermediate electrode 69L may include a first intermediate electrode barrier layer 69B, a first intermediate electrode seed layer 69S and a first intermediate electrode conductive layer 69C.

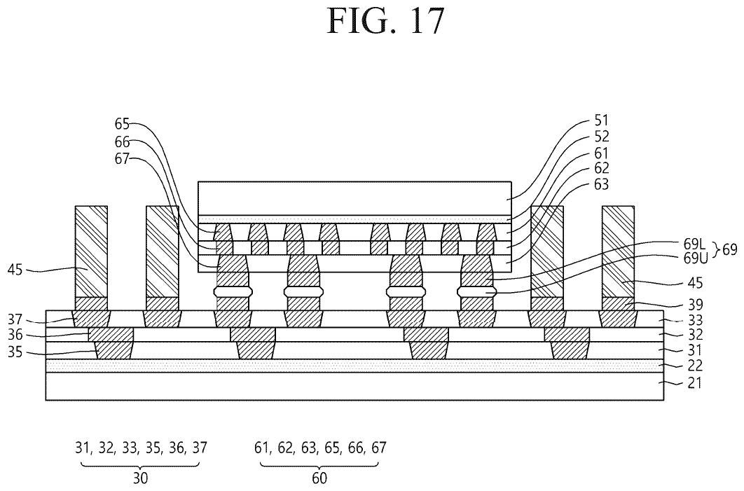

Referring to FIG. 17, the upper interconnect structure 60 may be bonded onto the lower interconnect structure 30. The second intermediate electrode 69U may contact the first lower electrode 39. The third upper insulating layer 63 may face the third lower insulating layer 33.

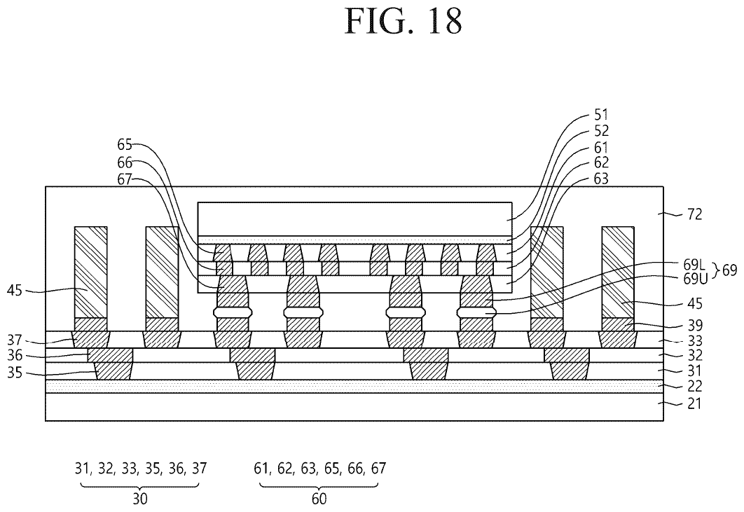

Referring to FIG. 18, a first encapsulation layer 72 which covers the pillar electrode 45 and the upper interconnect structure 60 may be formed on the lower interconnect structure 30. The first encapsulation layer 72 may extend between the lower interconnect structure 30 and the upper interconnect structure 60.

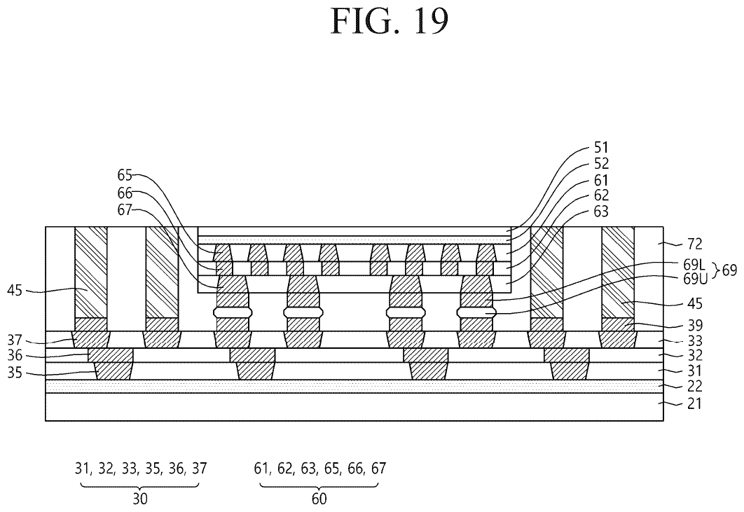

Referring to FIG. 19, by partially removing the first encapsulation layer 72, the pillar electrode 45 and the second substrate 51 may be exposed. A process for partially removing the first encapsulation layer 72 may include a grinding process. While the process for partially removing the first encapsulation layer 72 is performed, the second substrate 51 may be partially removed to be reduced in its thickness. The upper surfaces of the first encapsulation layer 72, the pillar electrode 45 and the second substrate 51 may form substantially the same plane.

According to the embodiments of the present disclosure, while the process for partially removing the first encapsulation layer 72 is performed, the second substrate 51 may serve to prevent damage to the upper interconnect structure 60.

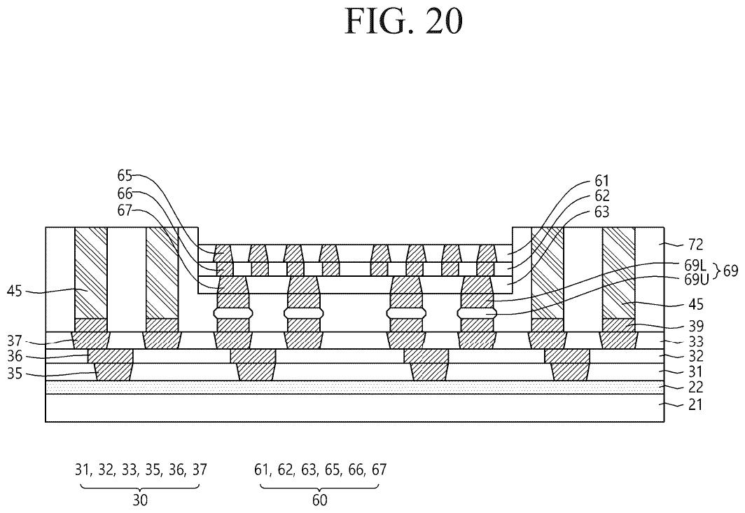

Referring to FIG. 20, by completely removing the second substrate 51 and the second buffer layer 52, the first upper insulating layer 61 and the first upper interconnect pattern 65 may be exposed. The upper surface of the first encapsulation layer 72 and the upper surface of the upper interconnect structure 60 may have a level difference H1 as illustrated in FIG. 3.

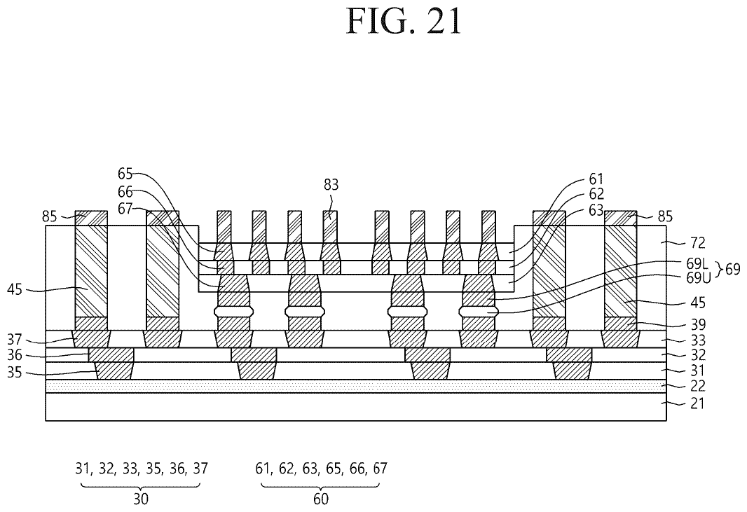

Referring to FIG. 21, a first upper electrode 83 may be formed on the first upper interconnect pattern 65, and a second upper electrode 85 may be formed on the pillar electrode 45. As illustrated in FIGS. 4 to 7, each of the first upper electrode 83 and the second upper electrode 85 may be formed to have various structures.

In an embodiment, as illustrated in FIG. 12, the first upper electrode 83 may include a first upper electrode barrier layer 83B, a first upper electrode seed layer 83S and a first upper electrode conductive layer 83C which are sequentially stacked. As illustrated in FIG. 11, the second upper electrode 85 may include a second upper electrode barrier layer 85B, a second upper electrode seed layer 85S and a second upper electrode conductive layer 85C which are sequentially stacked.

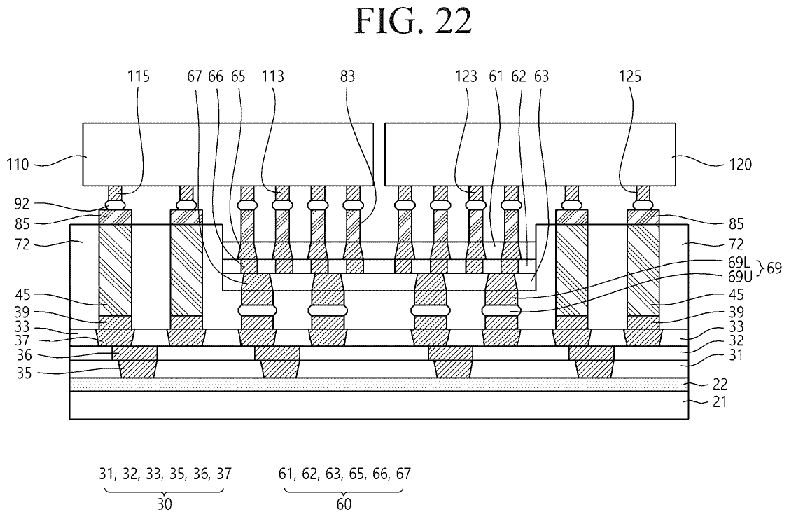

Referring to FIG. 22, a first semiconductor chip 110 and a second semiconductor chip 120 may be bonded onto the first upper electrode 83 and the second upper electrode 85.

A first chip electrode 113 may be disposed between the first semiconductor chip 110 and the first upper electrode 83. A second chip electrode 115 may be disposed between the first semiconductor chip 110 and the second upper electrode 85. Upper solder interconnections 92 may be formed between the first upper electrode 83 and the first chip electrode 113 and between the second upper electrode 85 and the second chip electrode 115.

A third chip electrode 123 may be disposed between the second semiconductor chip 120 and the first upper electrode 83. A fourth chip electrode 125 may be disposed between the second semiconductor chip 120 and the second upper electrode 85. Upper solder interconnections 92 may be formed between the first upper electrode 83 and the third chip electrode 123 and between the second upper electrode 85 and the fourth chip electrode 125.

As illustrated in FIG. 12, the first chip electrode 113 may include a first chip electrode barrier layer 113B, a first chip electrode seed layer 113S and a first chip electrode conductive layer 113C. As illustrated in FIG. 11, the second chip electrode 115 may include a second chip electrode barrier layer 115B, a second chip electrode seed layer 115S and a second chip electrode conductive layer 115C. The third chip electrode 123 may include a configuration similar to the first chip electrode 113. The fourth chip electrode 125 may include a configuration similar to the second chip electrode 115.

Each of the first semiconductor chip 110 and the second semiconductor chip 120 may include volatile memory, nonvolatile memory, a controller, an application processor, a microprocessor, or a combination thereof. Each of the first semiconductor chip 110 and the second semiconductor chip 120 may include dynamic random access memory (DRAM), static random access memory (SRAM), flash memory, magnetoresistive random access memory (MRAM), phase-change random access memory (PRAM), ferroelectric random access memory (FRAM), resistive random access memory (RRAM), or a combination thereof.

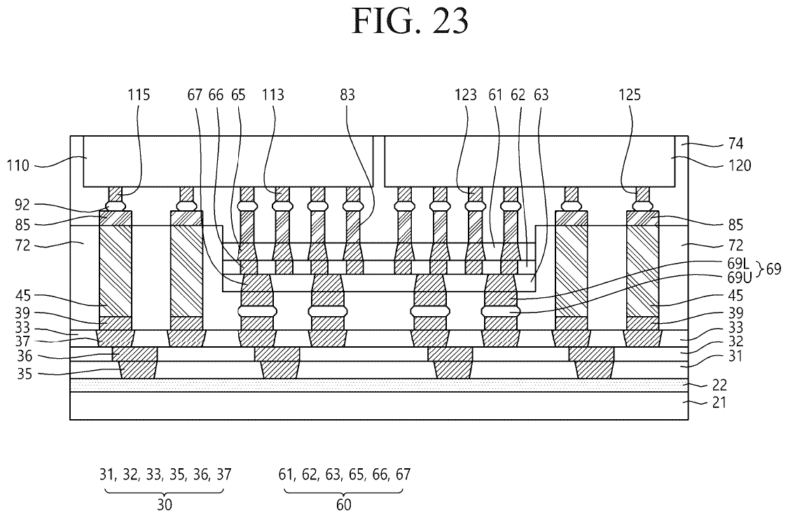

Referring to FIG. 23, a second encapsulation layer 74 which covers the first semiconductor chip 110 and the second semiconductor chip 120 may be formed on the first encapsulation layer 72 and the upper interconnect structure 60. The second encapsulation layer 74 may extend between the first encapsulation layer 72 and the first semiconductor chip 110, between the upper interconnect structure 60 and the first semiconductor chip 110, between the first encapsulation layer 72 and the second semiconductor chip 120 and between the upper interconnect structure 60 and the second semiconductor chip 120.

By partially removing the second encapsulation layer 74, the first semiconductor chip 110 and the second semiconductor chip 120 may be exposed. In an embodiment, while partially removing the second encapsulation layer 74, the back surfaces of the first semiconductor chip 110 and the second semiconductor chip 120 may be removed, so that thickness decreases.

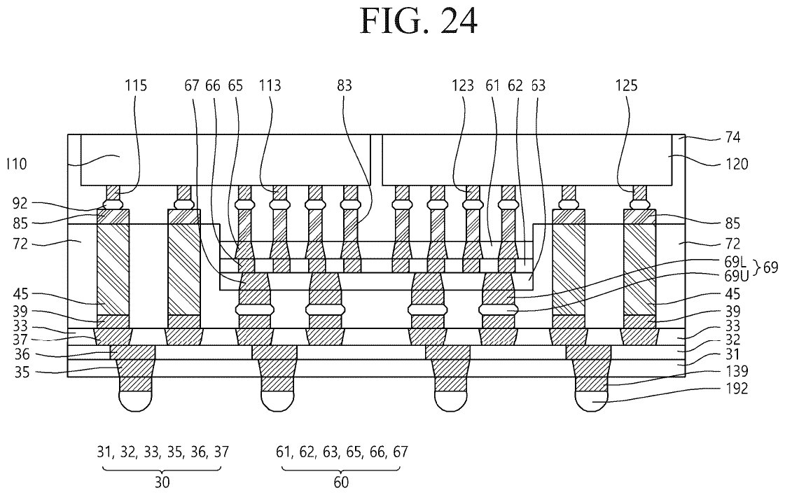

Referring to FIG. 24, a third buffer layer (not illustrated) and a third substrate (not illustrated) may be attached onto the second encapsulation layer 74, the first semiconductor chip 110 and the second semiconductor chip 120. By removing the first substrate 21 and the first buffer layer 22, the first lower insulating layer 31 and the first lower interconnect pattern 35 may be exposed.

A second lower electrode 139 may be formed on the first lower interconnect pattern 35. A lower solder interconnection 192 may be formed on the second lower electrode 139. As illustrated in FIG. 8, the second lower electrode 139 may include a second lower electrode barrier layer 139B, a second lower electrode seed layer 139S and a second lower electrode conductive layer 139C. By removing the third substrate (not illustrated) and the third buffer layer (not illustrated), one surfaces of the second encapsulation layer 74, the first semiconductor chip 110 and the second semiconductor chip 120 may be exposed.

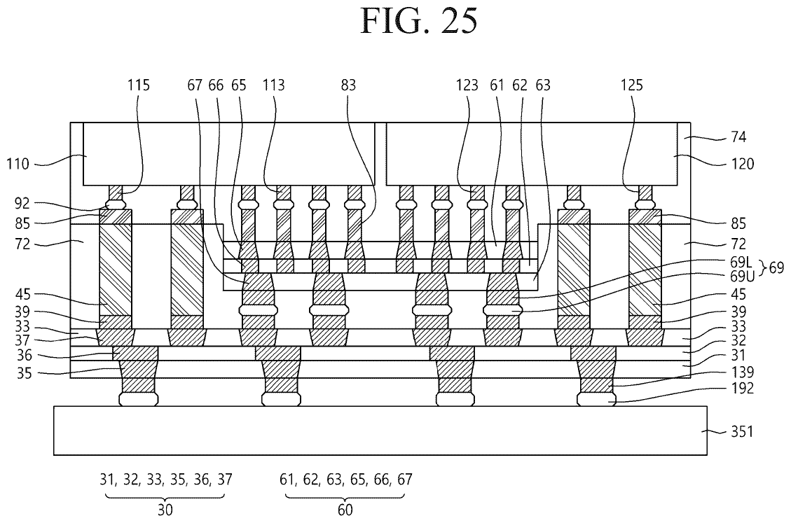

Referring to FIG. 25, the lower interconnect structure 30 may be mounted on a package substrate 351. The second lower electrode 139 and the lower solder interconnection 192 may be disposed between the package substrate 351 and the lower interconnect structure 30. The lower solder interconnection 192 may be bonded onto the package substrate 351. The package substrate 351 may include a printed circuit board, an interposer, a base chip, a communication chip, or a combination thereof.

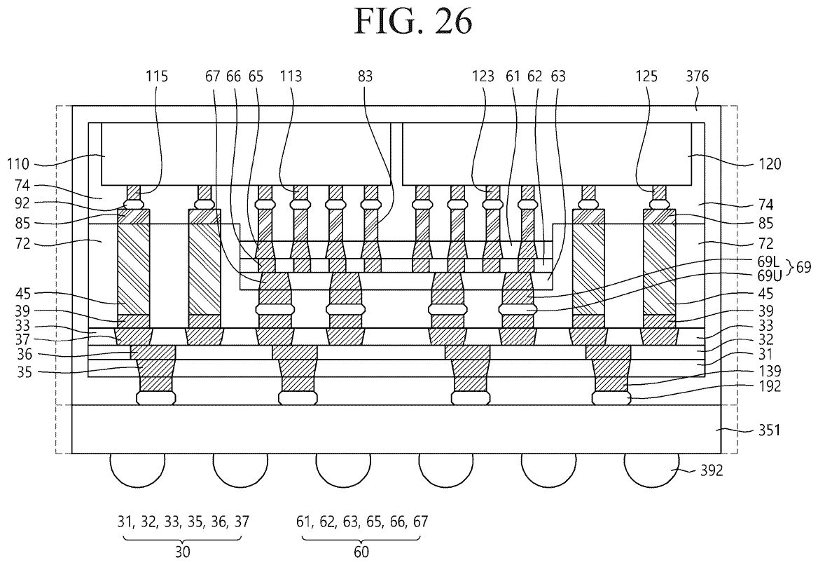

Referring to FIG. 26, a third encapsulation layer 376 which covers the lower interconnect structure 30, the first encapsulation layer 72, the second encapsulation layer 74, the first semiconductor chip 110 and the second semiconductor chip 120 may be formed on the package substrate 351. An external terminal 392 may be formed on the lower surface of the package substrate 351. Semiconductor packages may be divided using a singulation process. The external terminal 392 may include a solder ball, a conductive bump, a conductive pin, or a combination thereof.

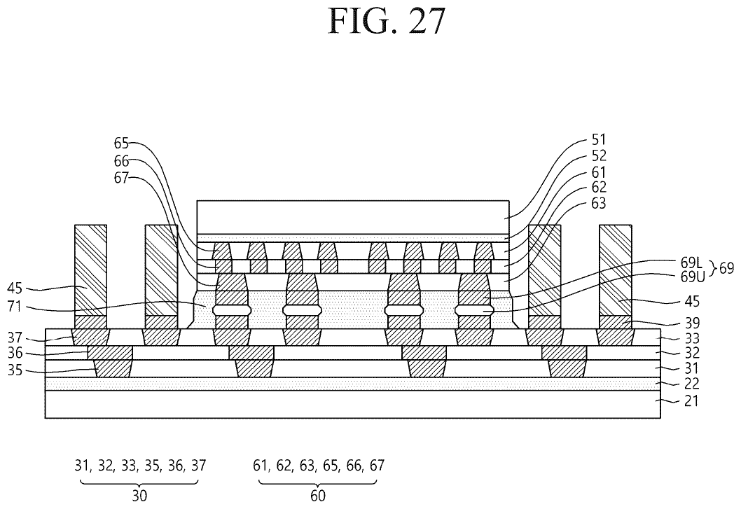

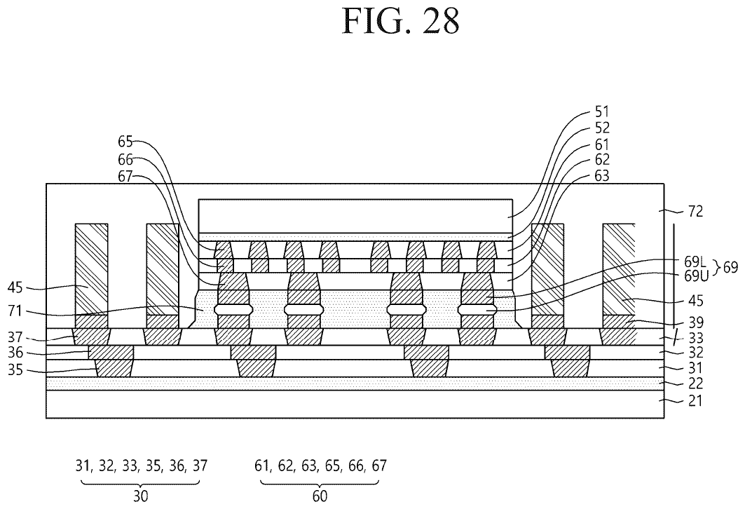

FIGS. 27 and 28 are cross-sectional views for explaining a method for forming a semiconductor package according to embodiments of the present disclosure.

Referring to FIG. 27, an underfill layer 71 may be formed between the lower interconnect structure 30 and the upper interconnect structure 60.

Referring to FIG. 28, a first encapsulation layer 72 which covers the pillar electrode 45, the upper interconnect structure 60 and the underfill layer 71 may be formed on the lower interconnect structure 30. A semiconductor package may be formed in a similar method as described above with reference to FIGS. 19 to 26.

Referring again to FIGS. 1 to 28, each of the first lower insulating layer 31, the second lower insulating layer 32, the third lower insulating layer 33, the first upper insulating layer 61, the second upper insulating layer 62 and the third upper insulating layer 63 may include a single layer or a multilayer. Each of the first lower insulating layer 31, the second lower insulating layer 32, the third lower insulating layer 33, the first upper insulating layer 61, the second upper insulating layer 62 and the third upper insulating layer 63 may include at least two selected from the group consisting of silicon (Si), oxygen (O), nitrogen (N), carbon (C) and boron (B). Each of the first lower insulating layer 31, the second lower insulating layer 32, the third lower insulating layer 33, the first upper insulating layer 61, the second upper insulating layer 62 and the third upper insulating layer 63 may include silicon oxide, silicon nitride, silicon oxynitride, silicon carbonitride (SiCN), silicon oxycarbonitride (SiOCN), low-k dielectric, or a combination thereof. Each of the first lower insulating layer 31, the second lower insulating layer 32, the third lower insulating layer 33, the first upper insulating layer 61, the second upper insulating layer 62 and the third upper insulating layer 63 may include insulating resin.

Each of the first lower interconnect pattern 35, the second lower interconnect pattern 36, the third lower interconnect pattern 37, the first lower electrode 39, the pillar electrode 45, the first upper interconnect pattern 65, the second upper interconnect pattern 66, the third upper interconnect pattern 67, the first intermediate electrode 69L, the first upper electrode 83, the second upper electrode 85, the first chip electrode 113, the second chip electrode 115, the third chip electrode 123, the fourth chip electrode 125 and the second lower electrode 139 may include a single layer or a multilayer. Each of the first lower interconnect pattern 35, the second lower interconnect pattern 36, the third lower interconnect pattern 37, the first lower electrode 39, the pillar electrode 45, the first upper interconnect pattern 65, the second upper interconnect pattern 66, the third upper interconnect pattern 67, the first intermediate electrode 69L, the first upper electrode 83, the second upper electrode 85, the first chip electrode 113, the second chip electrode 115, the third chip electrode 123, the fourth chip electrode 125 and the second lower electrode 139 may include metal, metal nitride, conductive carbon, or a combination thereof. Each of the first lower interconnect pattern 35, the second lower interconnect pattern 36, the third lower interconnect pattern 37, the first lower electrode 39, the pillar electrode 45, the first upper interconnect pattern 65, the second upper interconnect pattern 66, the third upper interconnect pattern 67, the first intermediate electrode 69L, the first upper electrode 83, the second upper electrode 85, the first chip electrode 113, the second chip electrode 115, the third chip electrode 123, the fourth chip electrode 125 and the second lower electrode 139 may include copper (Cu), tungsten (W), tungsten nitride (WN), titanium (Ti), titanium nitride (TiN), tantalum (Ta), tantalum nitride (TaN), cobalt (Co), nickel (Ni), silver (Ag), platinum (Pt), ruthenium (Ru), gold (Au), aluminum (Al), tin (Sn), or a combination thereof.

In an embodiment, each of the first lower interconnect barrier layer 35B, the third lower interconnect barrier layer 37B, the first lower electrode barrier layer 39B, the pillar electrode barrier layer 45B, the first upper interconnect barrier layer 65B, the third upper interconnect barrier layer 67B, the first intermediate electrode barrier layer 69B, the first upper electrode barrier layer 83B, the second upper electrode barrier layer 85B, the first chip electrode barrier layer 113B, the second chip electrode barrier layer 115B and the second lower electrode barrier layer 139B may include titanium (Ti), titanium nitride (TiN), tantalum (Ta), tantalum nitride (TaN), or a combination thereof. Each of the first lower interconnect seed layer 35S, the third lower interconnect seed layer 37S, the first lower electrode seed layer 39S, the pillar electrode seed layer 45S, the first upper interconnect seed layer 65S, the third upper interconnect seed layer 67S, the first intermediate electrode seed layer 69S, the first upper electrode seed layer 83S, the second upper electrode seed layer 85S, the first chip electrode seed layer 113S, the second chip electrode seed layer 115S and the second lower electrode seed layer 139S may include a conductive material such as copper. Each of the first lower interconnect conductive layer 35C, the third lower interconnect conductive layer 37C, the first lower electrode conductive layer 39C, the pillar electrode conductive layer 45C, the first upper interconnect conductive layer 65C, the third upper interconnect conductive layer 67C, the first intermediate electrode conductive layer 69C, the first upper electrode conductive layer 83C, the second upper electrode conductive layer 85C, the first chip electrode conductive layer 113C, the second chip electrode conductive layer 115C and the second lower electrode conductive layer 139C may include a copper layer by an electrolytic plating method.

Each of the second intermediate electrode 69U, the upper solder interconnection 92 and the lower solder interconnection 192 may include tin (Sn), silver (Ag), copper (Cu), bismuth (Bi), indium (In), zinc (Zn), gold (Au), palladium (Pd), antimony (Sb), or a combination thereof. Each of the first encapsulation layer 72, the second encapsulation layer 74 and the third encapsulation layer 376 may include an epoxy molding compound. The underfill layer 71 may include liquid polymer.

While the detailed embodiments of the present disclosure are disclosed in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

What is claimed is:

1. A semiconductor package comprising:
a lower interconnect structure comprising a lower insulating layer and a plurality of lower interconnect patterns;
a first encapsulation layer on the lower interconnect structure;
a pillar electrode penetrating the first encapsulation layer and connected to the plurality of lower interconnect patterns;
an upper interconnect structure disposed within the first encapsulation layer and comprising an upper insulating layer and a plurality of upper interconnect patterns, a first distance between an upper surface of the lower interconnect structure and an uppermost end of the first encapsulation layer and a second distance between the upper surface of the lower interconnect structure and an uppermost end of the upper interconnect structure, the first distance being larger than the second distance;
a second encapsulation layer on the first encapsulation layer; and
a semiconductor chip disposed within the second encapsulation layer, the semiconductor chip connected to the pillar electrode and the plurality of upper interconnect patterns.

2. The semiconductor package according to claim 1,
wherein the first encapsulation layer surrounds a side surface of the upper interconnect structure, and
wherein the first encapsulation layer extends between the lower interconnect structure and the upper interconnect structure.

3. The semiconductor package according to claim 1, wherein the first encapsulation layer is closer in distance to the semiconductor chip than the upper interconnect structure.

4. The semiconductor package according to claim 1, wherein the second encapsulation layer extends between the first encapsulation layer and the semiconductor chip and between the upper interconnect structure and the semiconductor chip.

5. The semiconductor package according to claim 4, wherein a thickness of the second encapsulation layer between the semiconductor chip and the upper interconnect structure is larger than a thickness of the second encapsulation layer between the semiconductor chip and the first encapsulation layer.

6. The semiconductor package according to claim 1, further comprising:
an underfill layer between the lower interconnect structure and the upper interconnect structure.

7. The semiconductor package according to claim 1, further comprising:
a first upper electrode disposed on the plurality of upper interconnect patterns and comprising a first thickness;
a second upper electrode disposed on the pillar electrode and comprising a second thickness;
a first chip electrode disposed between the semiconductor chip and the first upper electrode and comprising a third thickness;
a second chip electrode disposed between the semiconductor chip and the second upper electrode and comprising a fourth thickness; and
a plurality of upper solder interconnections between the first upper electrode and the first chip electrode and between the second upper electrode and the second chip electrode.

8. The semiconductor package according to claim 7,
wherein the first thickness of the first upper electrode is larger than the second thickness of the second upper electrode, and
wherein the third thickness of the first chip electrode is substantially the same as the fourth thickness of the second chip electrode.

9. The semiconductor package according to claim 7,
wherein the first thickness of the first upper electrode is substantially the same as the second thickness of the second upper electrode, and
wherein the third thickness of the first chip electrode is larger than the fourth thickness of the second chip electrode.

10. The semiconductor package according to claim 7, wherein the first thickness of the first upper electrode is larger than the second thickness of the second upper electrode, and
wherein the third thickness of the first chip electrode is larger than the fourth thickness of the second chip electrode.

11. The semiconductor package according to claim 7, wherein a horizontal width of the second chip electrode is larger than a horizontal width of the first chip electrode.

12. The semiconductor package according to claim 1, wherein at least one of the plurality of lower interconnect patterns comprise a first pitch, and
wherein at least one of the plurality of upper interconnect patterns comprise a second pitch smaller than the first pitch.

13. The semiconductor package according to claim 12,
wherein the lower interconnect structure comprises:
a first lower insulation layer;
a plurality of first lower interconnect patterns within the first lower insulating layer;
a second lower insulating layer on the first lower insulating layer;
a plurality of second lower interconnect patterns within the second lower insulating layer;
a third lower insulating layer on the second lower insulating layer; and
a plurality of third lower interconnect patterns disposed within the third lower insulating layer and comprising the first pitch, and
wherein the upper interconnect structure comprises:
a first upper insulating layer;
a plurality of first upper interconnect patterns disposed within the first upper insulating layer and comprising the second pitch;
a second upper insulating layer between the first upper insulating layer and the lower interconnect structure;
a plurality of second upper interconnect patterns within the second upper insulating layer;
a third upper insulating layer between the second upper insulating layer and the lower interconnect structure; and
a plurality of third upper interconnect patterns within the third upper insulating layer.

14. The semiconductor package according to claim 13, wherein the plurality of third upper interconnect patterns comprise substantially the same pitch as the plurality of third lower interconnect patterns.

15. The semiconductor package according to claim 13, further comprising:
an intermediate electrode between the plurality of third upper interconnect patterns and the plurality of third lower interconnect patterns.

16. The semiconductor package according to claim 1, further comprising:
a package substrate;
a lower solder interconnection between the package substrate and the lower interconnect structure; and
a third encapsulation layer disposed on the package substrate and covering the first encapsulation layer, the second encapsulation layer and the semiconductor chip.

17. A semiconductor package comprising:
a lower interconnect structure comprising a lower insulating layer and a plurality of lower interconnect patterns;
a first encapsulation layer on the lower interconnect structure;
a plurality of pillar electrodes penetrating the first encapsulation layer and connected to the plurality of lower interconnect patterns;
an upper interconnect structure disposed within the first encapsulation layer and comprising an upper insulating layer and a plurality of upper interconnect patterns, a first distance between an upper surface of the lower interconnect structure and an uppermost end of the first encapsulation layer and a second distance between the upper surface of the lower interconnect structure and an uppermost end of the upper interconnect structure, the first distance being larger than the second distance;
a second encapsulation layer on the first encapsulation layer; and
first and second semiconductor chips disposed within the second encapsulation layer, the first and second semiconductor chips connected to the plurality of pillar electrodes and the plurality of upper interconnect patterns.

18. The semiconductor package according to claim 17, further comprising:
a plurality of first upper electrodes on the plurality of upper interconnect patterns;
a plurality of second upper electrodes on the plurality of pillar electrodes;
a first chip electrode between the first semiconductor chip and the plurality of first upper electrodes;
a second chip electrode between the first semiconductor chip and the plurality of second upper electrodes;
a third chip electrode between the second semiconductor chip and the plurality of first upper electrodes;
a fourth chip electrode between the second semiconductor chip and the plurality of second upper electrodes; and
a plurality of upper solder interconnections between the plurality of first upper electrodes and the first chip electrode, between the plurality of second upper electrodes and the second chip electrode, between the plurality of first upper electrodes and the third chip electrode and between the plurality of second upper electrodes and the fourth chip electrode.

19. The semiconductor package according to claim 17, wherein the second encapsulation layer extends between the first encapsulation layer and the first semiconductor chip, between the upper interconnect structure and the first semiconductor chip, between the upper interconnect structure and the second semiconductor chip, and between the first encapsulation layer and the second semiconductor chip.

20. The semiconductor package according to claim 19, wherein a thickness of the second encapsulation layer between the first semiconductor chip and the upper interconnect structure is larger than a thickness of the second encapsulation layer between the first semiconductor chip and the first encapsulation layer, and
wherein a thickness of the second encapsulation layer between the second semiconductor chip and the upper interconnect structure is larger than a thickness of the second encapsulation layer between the second semiconductor chip and the first encapsulation layer.
